(19) United States
(12) Patent Application Publication
(10) Pub. No.: US 2007/0066096 A1
(43) Pub. Date: Mar. 22, 2007

(54) Hidden deck clip and hidden deck system

(76) Inventors: Timothy F. Gillis, Florence, MA (US); Martin G. Riccitelli, Agawam, MA (US)

Correspondence Address: ALIX YALE & RISTAS LLP, 750 MAIN STREET, SUITE 1400, HARTFORD, CT, 06103, US

(21) Appl. No.: 11/515,091

(22) Filed: Sep. 1, 2006

Related U.S. Application Data
(60) Provisional application No. 60/713,775, filed on Sep. 2, 2005.
(60) Provisional application No. 60/751,553, filed on Dec. 19, 2005.

(51) Int. Cl. H05K 1/00

(52) U.S. Cl. 439/76.1

(57) ABSTRACT

A clip for securing a board to a support member. The clip includes a body defining an aperture therethrough and a tab projecting from the body. The tab advantageously has a first position wherein the tab inner surface is disposed at a first angle to the body inner surface. In this embodiment the tab is elastically movable to a second position wherein the tab inner surface is disposed at a second angle to the body inner surface that is less than the first angle. In some embodiments the clip is adapted for use with boards having opposing, longitudinally extending protruding and inset sides. The clip is disposed over the protruding side and an elongated fastener is disposed through the clip and the protruding side and into the support member. The inset side of a second board adjacent the secured protruding side can be biased toward the support member by contact of that side with the clip tab. Also a system and method of using the clip to secure a board to a support member.

### CROSS REFERENCE TO RELATED APPLICATIONS

This application claims the benefit of U.S. Provisional Application No. 60/713,775, filed Sep. 2, 2005 and U.S. Provisional Application No. 60/751,553, filed Dec. 19, 2005, the contents of each of which are incorporated herein by reference in their entirety.

### FIELD OF THE INVENTION

The present disclosure relates generally to fasteners for securing boards to supporting members. The present disclosure is particularly advantageous for use as a hidden deck clip and system for securing cover boards to supporting members in a deck system.

### BACKGROUND OF THE INVENTION

Fasteners such as nails or screws for securing boards to supporting members such as joists are well known. More recently, so called “hidden decking” systems which fasten cover boards to joists without having a fastener penetrate the visible, top surface of the cover board have come into demand. Many of these hidden decking systems require extensive preparation of the decking system components such as pre-drilling tracks on the joists, pre-drilling slots or holes in cover boards for fasteners, or gluing of the cover boards to the joists. Some hidden decking systems must be substantially installed from below the deck, a time consuming, expensive and potentially dangerous procedure.

### SUMMARY OF THE INVENTION

One aspect of the invention provides a clip. The clip has a body with inner and outer surfaces defining one or more apertures therethrough. The aperture may comprise an extruded portion. One or more tabs extend from the body. Advantageously, the tab and the body inner surface are in angular relationship. In some embodiments that tab may extend substantially the length of the body. Each tab advantageously comprises a stop angularly projecting from the tab distal portion. In another embodiment the clip is simplified comprising a limited body defining a single aperture and a single tab angularly projecting from the body. The simplified clip advantageously includes an anti-rotation device.

The clip is advantageously used with a profiled cover board having a protruding side and an inset side. The body inner surface of the clip is disposed on one portion of the protruding side and the tab is positioned adjacent to, or in contact with, another portion of the protruding side. A fastener is disposed through the aperture, through the cover board protruding side and into a support member. The inset side of a second cover board is positioned adjacent to and partially covering the protruding side of the first cover board and fastened clip so that the tab is elastically displaced toward the first cover board protruding side. In some embodiments the displaced tab resiliently biases the second cover board. A second clip and fastener is used to fasten the second cover board protruding side to the support member. Additional cover boards can be fastened in a similar manner.

In some embodiments the clip may be advantageous as compared to the traditional method of driving fasteners from the cover board exposed surface through the cover board and into the support member. In some embodiments each cover board may be fastened only at the protruding side since the inset side is held in position by the clip and protruding edge of an adjacent cover board. This saves time and fasteners compared to conventional cover boards that require fastening on or adjacent both sides of each board. The clip may be wholly or partially covered by the adjacent cover board inset side and is not readily apparent to an observer standing on a finished deck. Embodiments of the cover board including one or more longitudinally extending radiused projections or ribs can further help conceal the fastened clip. The clip may provide a consistent space between the protruding side and inset side of two adjacent cover boards to allow for water drainage. The inset side is typically not rigidly fastened to the support member with fasteners. Rather, the biased tab provides a resilient force against one inset side surface to limit curling or shifting of that inset side away from the support member. The resilient force provided by the biased tab contact with the inset side surface also allows the inset side freedom to move as the width of the cover board changes due to material shrinkage or swelling. The inventors believe that use of the disclosed clip in a deck system would provide a stiffness increase for each cover board of more than ten percent. This increase in stiffness would be beneficial to cover boards that are susceptible to bending under load and may allow the use of a thinner cover board. The predefined fastener apertures consistently locate the fastener to save time and help minimize misapplication of the fastener. Clip variations comprising an extruded aperture help retain the clip to the cover board and further help locate the fastener. Workers can readily position and fasten cover boards and clips from above the deck structure. Some embodiments of the profiled cover board allow fastening of the board through the upwardly facing, protruding side surface without a clip if desired.

In general, the embodiments of the invention may be alternately formulated to comprise, consist of, or consist essentially of, any appropriate components herein disclosed. The embodiments of the invention may additionally, or alternatively, be formulated so as to be devoid, or substantially free, of any components, materials or species used in the prior art compositions or that are otherwise not necessary to the achievement of the function and/or objectives of the present invention.

When the word “about” is used herein it is meant that the amount or condition it modifies can vary some beyond that so long as the advantages of the disclosed device are realized. Practically, there is rarely the time or resources available to very precisely determine the limits of all the parameters of a device because to do so would require an effort far greater than can be justified at the time the device is being developed to a commercial reality. The skilled artisan understands this and expects that the disclosed results might extend, at least somewhat, beyond one or more of the limits disclosed. Later, having the benefit of the inventors disclosure and understanding the concept and embodiments disclosed including the best mode known to the inventor, the inventor and others can, without inventive effort, explore beyond the limits disclosed to determine if the invention is realized beyond those limits and, when embodiments are found to be without any unexpected characteristics, those embodiments are within the meaning of the term about as used herein. It is not difficult for the artisan or others to determine whether such an embodiment is either as expected or, because of either a break in the continuity of results or one or more features that are significantly better than reported by the inventor, is surprising and thus an unobvious teaching leading to a further advance in the art.

### BRIEF DESCRIPTION OF THE DRAWINGS

Referring now to the drawings wherein like elements are numbered alike in the several Figures:

FIG. 1 is a perspective view of an embodiment of a clip.

FIG. 2 is an edge view of the clip of FIG. 1.

FIG. 3 is an end view of the clip of FIG. 1.

FIG. 4 is an end view of a plurality of clips positioned adjacent a plurality of profiled cover boards.

FIG. 5 is an end view, broken away and partially in phantom, of a plurality of cover boards secured to a support member by a plurality of clips and a plurality of fasteners.

FIG. 6 is a top view of an embodiment of a clip.

FIG. 7 is a top view of an embodiment of a clip.

FIG. 8 is a perspective view of an embodiment of a clip.

FIG. 9 is a perspective view of an embodiment of a clip.

FIG. 10 is an end view of a plurality of clips positioned adjacent a plurality of profiled cover boards.

FIG. 11 is a top plan view, broken away and partially in phantom, of an embodiment of a cover board and an embodiment of a clip disposed with respect to a joist at an angle other than ninety degrees.

FIG. 12 is a top plan view, broken away and partially in phantom, of an embodiment of a clip fastening two abutting cover boards to a joist.

FIG. 13 is a perspective view of an embodiment of a profiled cover board with an embodiment of a clip disposed adjacent the outwardly projecting surfaces.

FIG. 14 is an enlarged, partial end view of a plurality of broken away profiled cover boards arranged in side by side relation with one embodiment of a clip biased therebetween.

FIG. 15 is an end view of an embodiment of a plurality of profiled cover boards.

FIG. 16 is an end view of an embodiment of a plurality of profiled cover boards.

FIG. 17 is an end view of an embodiment of a clip comprising an extruded body portion around the aperture.

FIG. 18 is a perspective view of an embodiment of a clip comprising an extruded body portion around each of the apertures.

FIG. 19 is a perspective view of another embodiment of a clip.

FIG. 20 is an end view of a plurality of profiled cover boards and a plurality of the clips of FIG. 19.

FIG. 21 is a perspective view, broken away at one end, of a plurality of an embodiment of profiled cover boards with an embodiment of a clip disposed adjacent the protruding edge.

FIG. 22 is an exploded, broken away, end view of the profiled cover boards and clip of FIG. 21.

### DETAILED DESCRIPTION

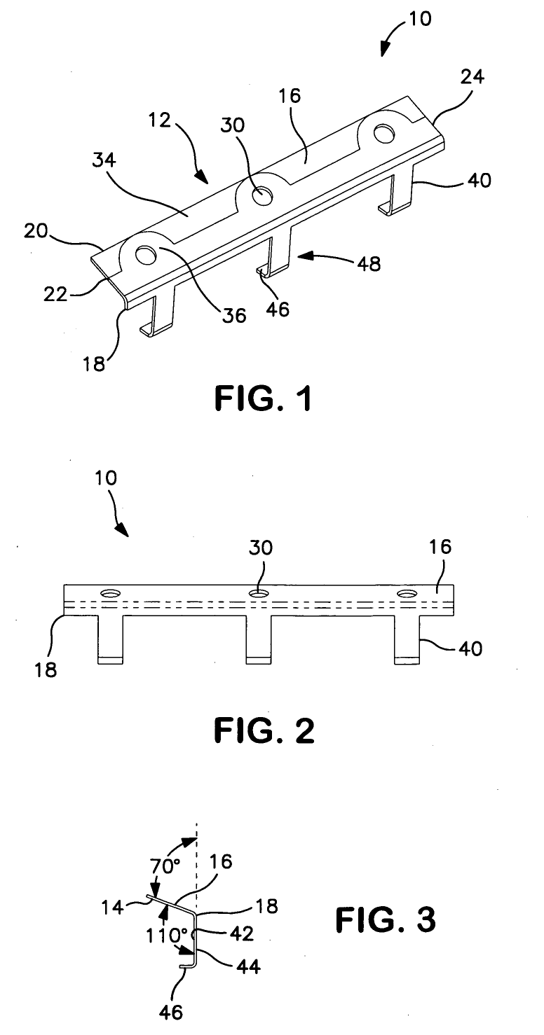

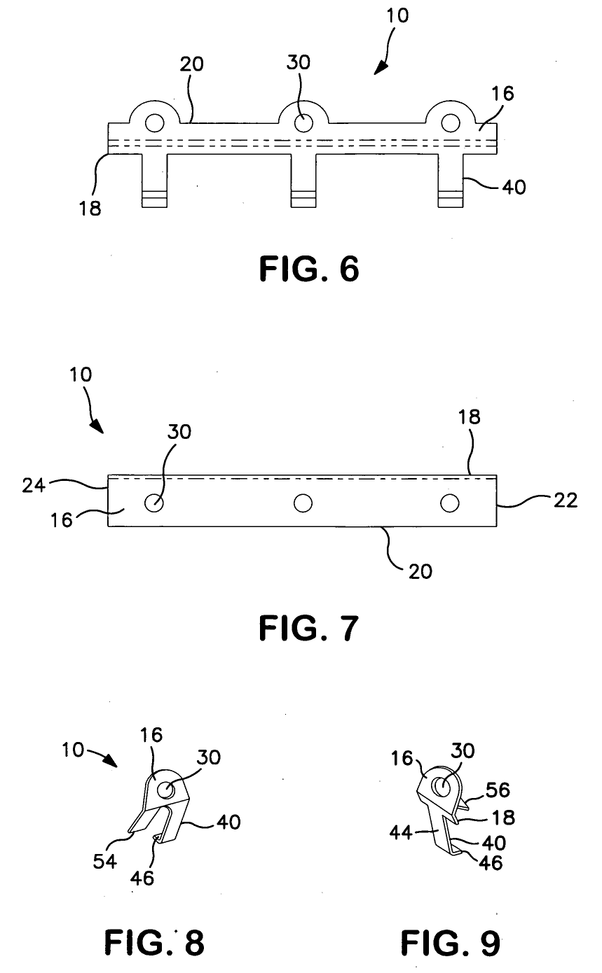

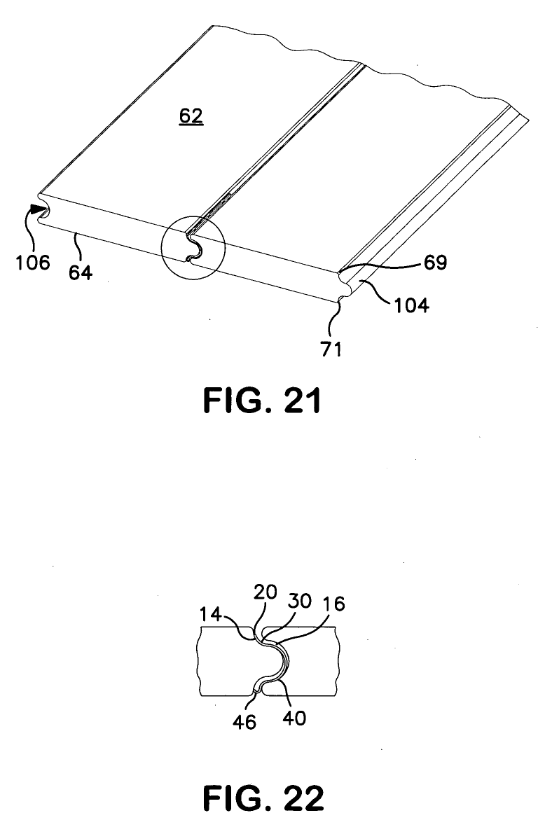

With reference to the embodiment shown in FIG. 1, the clip 10 compromises a body 12 having an inner surface 14 (shown in FIG. 3) and an outer surface 16. The body may be planar as exemplified in FIG. 6 or curved as exemplified in FIG. 21. At the present time a substantially planar body 12, for example as shown in FIGS. 6 and 7 is considered advantageous.

The clip 10 comprises a longitudinal edge 20 and opposing ends 22, 24. In some embodiments the clip 10 comprises a second longitudinal edge 18 opposing longitudinal edge 20. Each longitudinal edge 18, 20 may independently be coplanar with the body 12 (see edge 20) or angularly arranged with respect to the body 12 (see edge 18). An aperture 30 is defined in the body 12 and connects the body inner surface 14 to the body outer surface 16. In some embodiments such as shown in FIG. 1 the body 12 is longitudinally elongated between the ends 22, 24 and defines more than one aperture (each 30). In other embodiments such as shown in FIGS. 8 and 9 the clip 10 is simplified with a smaller body 12.

With reference to FIG. 1 the body 12 may include one or more raised portions (each 34) and/or one or more depressed portions (each 36). The depressed portion 36 can be advantageous for allowing the head of a fastener (not shown) to be inset therein.

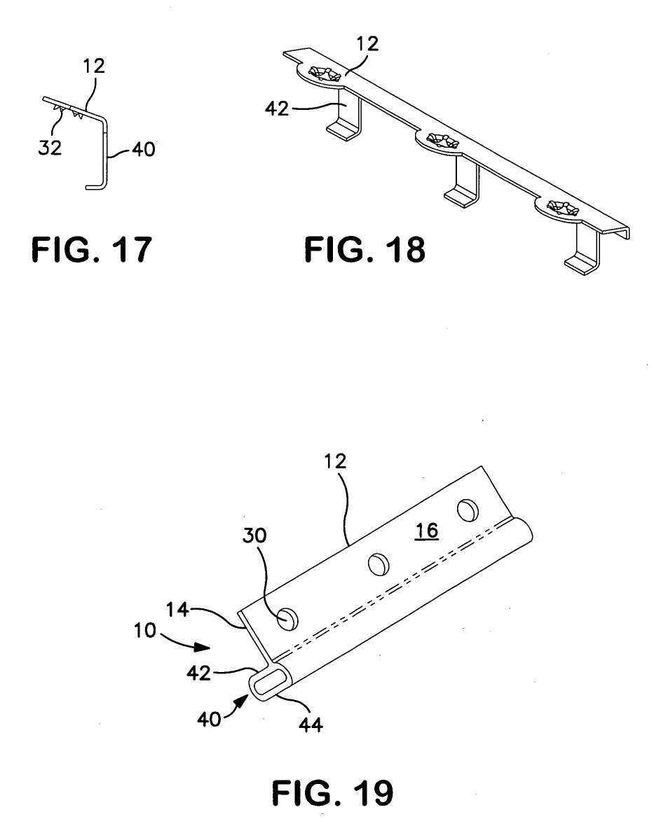

With reference to FIGS. 17 and 18 the portion of the body 12 surrounding the aperture 30 may be extruded or displaced. In this variation the body outer surface 16 around the aperture 30 may be depressed and the body inner surface 14 around the aperture 30 may be extruded or displaced beyond the inner surface 14. The extruded material 32 may form a continuous ring around the aperture 30 (not shown) or it can form two or more segments. As shown best in FIG. 17 the extruded material 32 may define one or more barbs. In use the extruded material very slightly, but not substantially, penetrates the adjacent board to help maintain the clip in position. The depressed outer surface may also help guide the elongated shank of a fastener through the aperture 30 and may help accommodate the head of the fastener. It should be noted that the extruded material 32 does not hold adjacent boards together.

With reference to FIG. 1, one or more tabs (each 40) will typically project from the body 12. The tab will have an inner surface 42 and an opposing outer surface 44 (shown in FIG. 3). The tab 40 is not limited in size and can extend longitudinally from one end 22 of the body 12 to the opposing end 24 (not shown), although use of one or more narrow tabs 40 as shown in FIG. 1 is presently considered advantageous. The tab 40 can project from a coplanar or angularly arranged longitudinal edge (20 or 18 respectively). Advantageously, a stop 46 projects angularly from a distal portion 48 of the tab 40.

The clip 10 is typically arranged to be generally complementary to the protruding edge of a profiled cover board described below. In these embodiments the clip is arranged so that the body inner surface 14 can be disposed in contact with a portion of the protruding edge and the tab inner surface can be disposed adjacent to, or in contact with, another portion of the protruding edge. In some embodiments the tab 40 is arranged at an angle with respect to the body inner surface 14 and the body outer surface 16. In one advantageous variation shown in FIG. 3 the tab inner surface 42 is arranged at an angle of about 110 degrees with respect to the body inner surface 14. In other embodiments the tab 40 may be curved (see FIG. 22) or other non-linear shape.

Advantageously, the clip comprises an anti rotation device 52 to lessen the potential for rotation of the clip during fastening. In elongated variations of the clip 12 such as shown in FIG. 1 the extended length of the body 12 and, if present, the multiple tabs (each 40) will act as an anti-rotation device 52. In embodiments of the clip 10 such as shown in FIG. 8 the anti-rotation device 52 comprises a leg 54 angularly projecting from the body 12 and preventing rotation during fastening by providing mechanical interference with an adjacent cover board. In embodiments of the clip 10 such as shown in FIG. 9 the anti-rotation device 52 comprises a barb 56 projecting from the clip 10. The barb 56 pierces an adjacent cover board during fastening to prevent rotation.

In some embodiments such as shown in FIGS. 1 and 6 the body 12 has an elongated length of about 4 inches and defines three apertures (each 30) therein. One aperture 30 is disposed about 0.5 inches from each side 22, 24 of the body. A third aperture 30 is disposed between the outermost apertures 30, 30. The longitudinal edge 18 is angularly arranged with respect to the body inner surface 14 and a plurality of tabs (each 40) project about 0.5 inches from the longitudinal edge 18. The centerline of each tab 40 is generally aligned with the centerline of a respective aperture 30. Each tab inner surface 42 defines an angle of about 110 degrees with respect to the body inner surface 14. A stop 46 projects angularly and inwardly about 0.2 inches from the distal portion 48 of each tab 40.

The clip 10 is advantageously formed from a single piece of bent metal. The use of sheet metal will provide a clip with a desirable thin cross section. The sheet metal can be bent and cut between dies in a press to form the clip 10. The sheet material can optionally be coated to provide a desired color or lessen rusting of the in-use clips. In embodiments wherein the tab provides resiliency as later described, the metal is advantageously stainless spring steel and more advantageously AISI 301 stainless steel having a spring temper. However, the clip 10 may be formed from any material having sufficient strength to resist breaking in use. Other materials are believed to include, for example, polymers and polymeric composites.

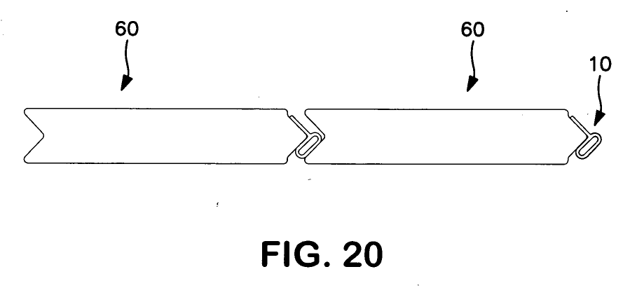

In another variation shown in FIG. 19 the clip 10 comprises a body 12 having inner and outer surfaces (14, 16 respectively). A tab 40 having inner and outer faces (42, 44 respectively) projects from the body. In this variation the tab 40 is formed of a resilient material, for example an elastomer, and defines a hollow core. The body 12 may be the same resilient material as the tab 40 or it may be a different material, for example metal. The resilient material allows the tab 40 to provide a resistive reactive force or bias on adjacent cover boards as shown in FIG. 20. In other variations the tab may be solid or filled with a more or less resilient material to tailor the force provided. In still other variations the clip may be provided in a continuous length. The continuous length may be cut as needed or disposed against the full length of a cover board.

The clip 10 is advantageously used with profiled cover boards. The profiled cover board may be, for example, a natural wood product, a natural wood product treated with materials such as preservatives (for example CCA or other pressure treated wood products), a polymer comprising composite product or a completely polymer product.

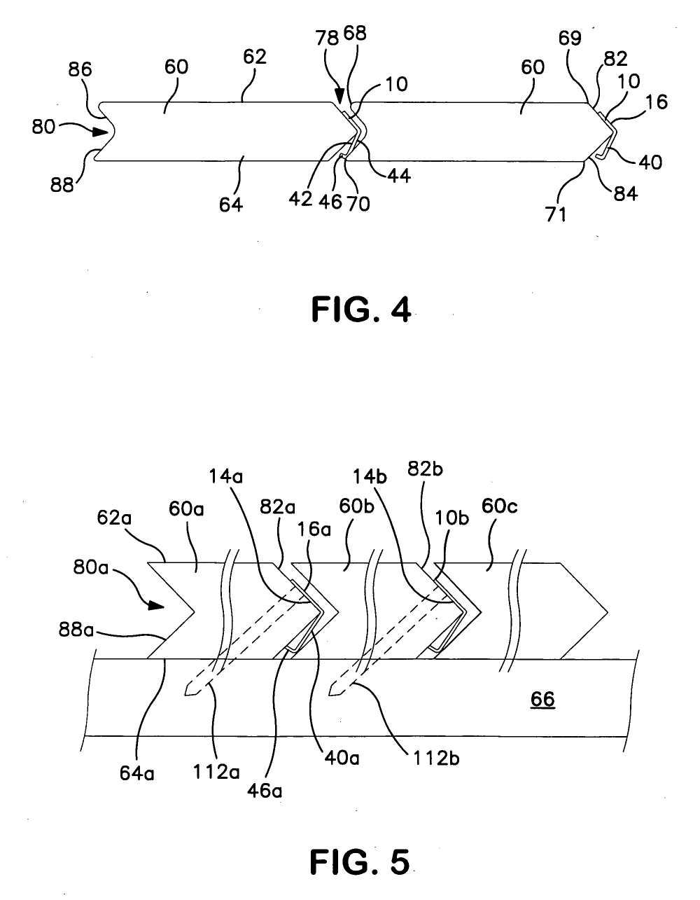

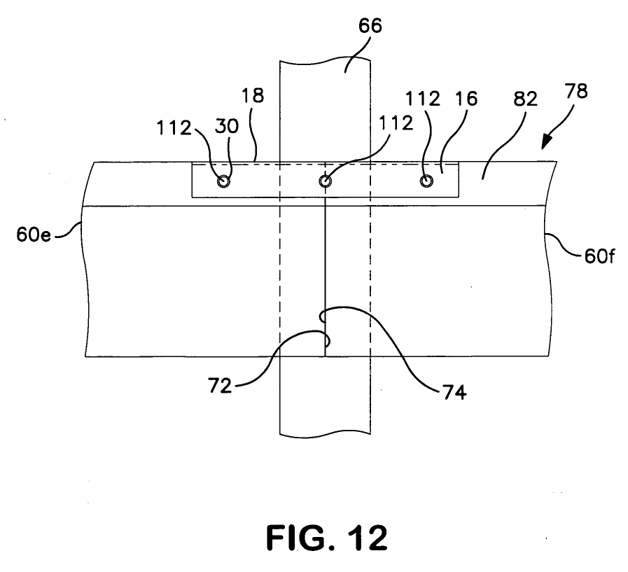

With reference to FIG. 4, profiled cover boards 60 will have a generally planar exposed surface 62 defined between longitudinally extending edges 68, 69. A generally planar support surfaces 64 is defined between longitudinally extending edges 70, 71. Typically, the exposed surface 62 will face upwardly and is exposed or visible in use and the opposing support surface 64 will face downwardly and is disposed adjacent or over a support member 66 (shown, for example, in FIG. 5). The exposed surface 62 may be patterned, including wood grain patterning, to provide a desirable visual appearance. In some embodiments the exposed 62 and support 64 surfaces are interchangeable. A cover board 60 will have opposing, longitudinal extending sides 68, 70 and opposing spaced ends 72, 74 (see FIG. 12). In one advantageous variation the typical cover board 60 has a width of about six inches between opposing edges 68, 69 and a thickness of about seven eighths to about one and one eighth inches between opposing surfaces 62, 64. The board length between ends 72, 74 is variable and may be adjusted for economic, manufacturing and installation reasons.

Typical cover boards (not shown) used for decks are rectangular in cross section with opposing, planar sides. Each typical side extends in planar fashion from the exposed surface to the support surface, is parallel with the other and is arranged at an angle of ninety degrees with the exposed and support surfaces.

As used herein the profiled cover board 60 will have a longitudinally extending, protruding side 78 projecting outwardly from edges 69, 71 and an opposing, longitudinally extending inset side 80 projecting inwardly from edges 68, 70. The inset side 80 defines a cavity within the cover board 60 open on one side. In some embodiments the cavity may extend between ends 72, 74. The protruding side 78 is generally complementary to the inset side 80 so that in use the protruding side 78 and clip 10 of a first cover board can fit at least partially within the inset side 80 of a second cover board (see, for example, FIGS. 4, 14 or 22). The size and shape of the protruding side can vary and can be, for example, rounded (FIG. 22), square (nor shown) or angled (FIG. 4), as long as the protruding side 78 provides sufficient surface area to allow a fastener to be driven therethrough and the protruding side 78 and/or clip 10 can fit at least partially within the complementary inset side 80. Some embodiments of profiled cover boards 60 are exemplified in FIGS. 4, 10, 13-16 and 21.

FIG. 4 illustrates an embodiment of a cover board 60 having a profile believed to be advantageous for use with natural wood cover boards. This embodiment of a profiled cover board 60 has a protruding side 78 and an opposing inset side 80 extending longitudinally along the board length. The protruding side 78 comprises outwardly projecting, angularly arranged surfaces 82, 84. The inset side 80 comprises inwardly projecting, angularly arranged surfaces 86, 88. Surface 82 can be arranged at any useful angle with respect to surface 84 and surface 86 can be arranged at any useful angle with respect to surface 88. In one advantageous variation the angularly arranged surfaces 82, 84, 86, 88 define an angle of about 45 degrees with respect to a centerline. Machining can be used to provide the protruding side surfaces 82, 84 and/or the inset side surfaces 86, 88.

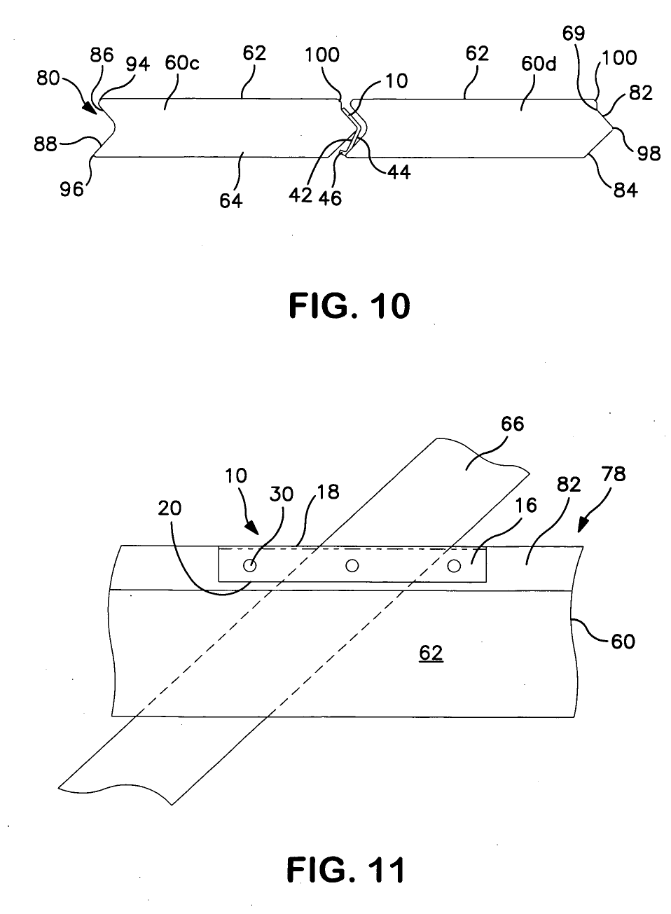

FIG. 10 illustrates an embodiment of a cover board 60 having a profile believed to be advantageous for use with polymer comprising cover boards. This embodiment of a profiled cover board 60 may comprise a radius 94 at the intersection of inwardly projecting surface 86 and cover board exposed surface 62 and a radius 96 at the intersection of inwardly projecting surface 88 and cover board support surface 64. This embodiment can optionally include a radius 98 at the intersection of the outwardly projecting surfaces 82, 84 and a radiused projection or rib 100 adjacent edge 69. When the cover board 60 is secured to a support member 66 with a clip 10 and elongated fastener 112 the radiused projection or rib 100 can help shield the clip 10 from view. Shielding of the clip from view provides the structure with a fastener free appearance that is desirable in some applications. In one advantageous variation the inwardly projecting surfaces 86, 88 and/or outwardly projecting surfaces 82, 84 define an angle of about 45 degrees with respect to a centerline. The side surfaces can be formed during the manufacturing process or by subsequent machining.

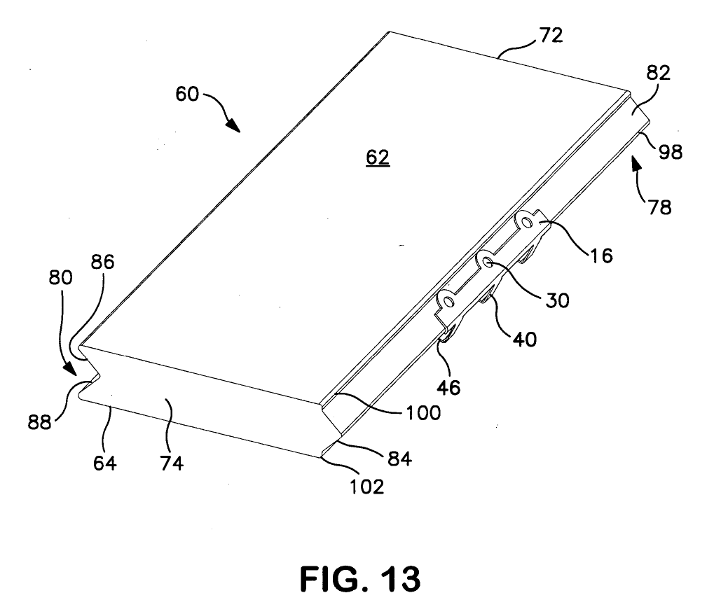

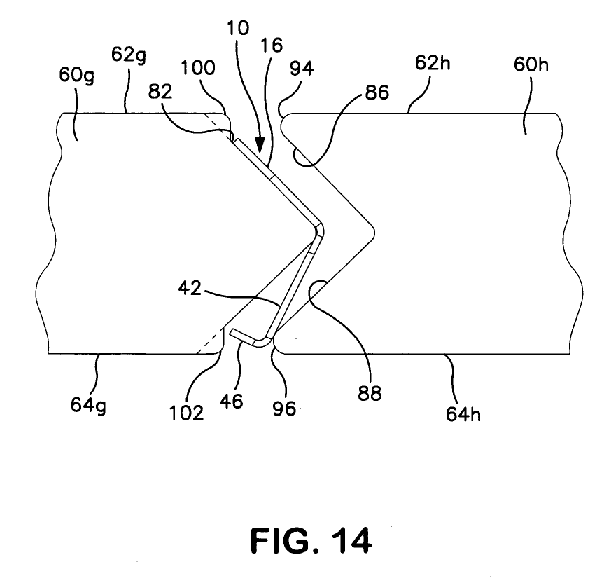

FIGS. 13, 14, 15 and 16 illustrate some other variations of a profiled cover board 10 believed to be advantageous for use with polymer comprising cover boards. The variation of FIGS. 13 and 14 is similar to that of the variation shown in FIG. 10 with the addition of a longitudinally extending, radiused projection or rib 102 adjacent edge 71. Using two projections 100, 102, one adjacent each surface (62, 64 respectively) of the profiled cover board 60, simplifies installation as it allows either surface 62, 64 of the profiled cover board to be oriented upwardly and exposed to the viewer while retaining the advantageous ability to shield the clip 10 from view.

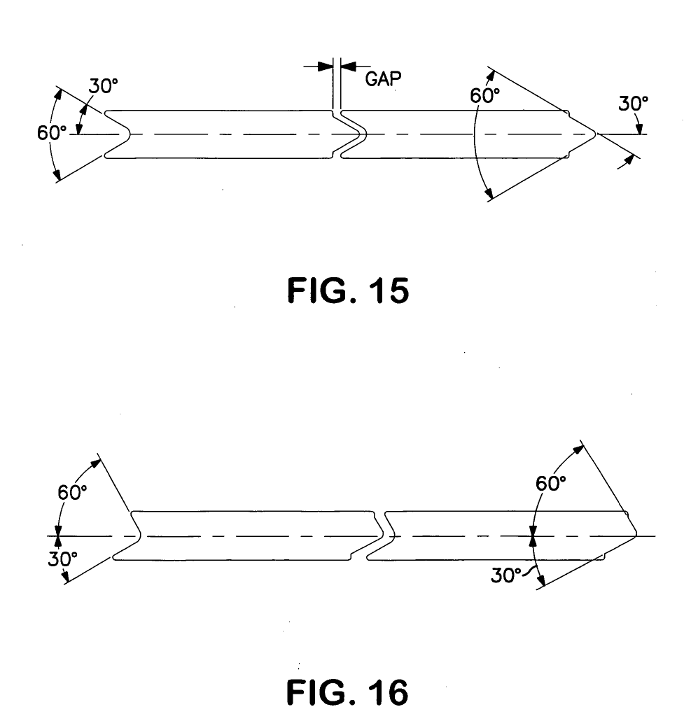

The angle defined by the inwardly projecting surfaces 86, 88 and/or outwardly projecting surfaces 82, 84 is not believed to be critical. However, outwardly projecting surface 82 must provide sufficient surface area to allow a fastener to be driven through and outwardly projecting surface 84 should have some engagement within the inset side 80 of an adjacent cover board 60. In one advantageous variation exemplified in FIG. 10 the inwardly projecting surfaces 86, 88 and/or outwardly projecting surfaces 82, 84 define an angle of about 45 degrees with respect to a centerline. In another variation shown in FIG. 15 the inwardly projecting surfaces 86, 88 and/or outwardly projecting surfaces 82, 84 define an angle of about 30 degrees with respect to a centerline. In another variation shown in FIG. 16 inwardly projecting surface 86 and outwardly projecting surface 82 define an angle of about 60 degrees with respect to a centerline and inwardly projecting surface 88 and outwardly projecting surface 84 define an angle of about 30 degrees with respect to a centerline. The profiled side surfaces 78, 80 can be formed during the manufacturing process or by subsequent machining.

FIGS. 21 and 22 illustrate an embodiment of a cover board having rounded protruding 78 and inset 80 sides. This embodiment of a profiled cover board 60 has the protruding side 78 and an opposing inset side 80 extending longitudinally along the board length. The protruding side 78 comprises an outwardly projecting, rounded rib 104. The inset side 80 comprises inwardly projecting, rounded cavity 106. This cover board embodiment may advantageously be used with a clip 10 having a rounded body 12 and rounded tab 40. The protruding side 78 is generally complementary to the inset side 80 so that in use the protruding side 78 and clip 10 of a first cover board can fit at least partially within the inset side 80 of a second cover board It would be possible to remove material from the cover board, either internally or from one surface. Such removal might be done during manufacture of a polymer comprising cover board, for example by making the board thinner or including slots, ridges or apertures in one planar surface of the cover board. In other embodiments machining of wood or polymer comprising cover boards would provide, for example, slots, ridges or apertures in one planar surface of the cover board. The material removed surface could be positioned adjacent the support members and would not be visible in use. A cover board with material removed can advantageously have lighter weight and require less material than a board without such removal.

For simplicity the following disclosure will reference one method of using one embodiment of the clip 10 and one embodiment of the cover board 60 to provide a deck surface. It should be noted that FIGS. 4-5, 10-16 and 20 exemplify various aspects of the clip and/or cover boards in use but do not illustrate a complete deck system. It should also be noted that the clip and/or profiled cover boards are useful in other embodiments, environments, combinations and assembly sequences and all such uses are encompassed herein. For example, the disclosed clip 10 and/or cover boards 60 can be used in boardwalks, benches, stair treads and seating. The use of letter suffixes denotes an element present on an item having that suffix. With reference to. FIG. 5 the decking system will typically comprise a framework of support members each 66 (one shown) secured to one another. Such a framework of support members is known and comprises posts, rim joists, ledgers and joists. A first cover board 60a is positioned so that the end 72 to end 74 length will span a plurality of support members 66. Typically, the inset side 80a of the first cover board 60a would be adjacent a ledger or rim joist (not shown). The inner surface 14a of a first clip 10a is positioned adjacent the protruding side upward facing surface 82a of the first cover board 60a. The elongated shank of a fastener 112a, such as a screw or nail, is disposed through the aperture 30a, through the protruding side upward facing surface 82a and partially into the support member 66. Depending on the angle of tab 40a with respect to the body inner surface 14a the tab stop 46a may or may not be disposed against the protruding side downward facing surface 84a of the first cover board 60a. Typically multiple clips will be spaced along the longitudinal length of the first cover board protruding side 78a so that a plurality of elongated fasteners can be used to fasten the board 60a to a plurality of support members 66.

The inset side 80b of a second cover board 60b is disposed over the protruding side 78a and fastened clip 10a of the first cover board 60a. The inner surface 14b of a second clip 10b is positioned adjacent the upward facing surface 82b of the second cover board 60b protruding side 78b and the combination is pushed toward the first cover board 60a to bias the tab stop 46a of fastened clip 10a toward the downward facing surface 84a of the first cover board 60a. Once the second cover board 60b is properly positioned, a second fastener 112b is disposed through the aperture 30b of the second clip 10b and the protruding side upward facing surface 82b of the second cover board 60b into the support member 66 to maintain this position. This sequence is followed with additional cover boards and clips until the deck surface is finished. It should be noted that tab stop 46a, tab 40a and body 12a do not substantially penetrate into either the first or second cover boards 60a, 60b. The protruding sides are secured to the support member by fasteners. The inset sides 80 are not rigidly fastened to the support member with fasteners, rather, the fastened biased tabs 40 provide a resilient force against inset side surface 88 to limit curling or shifting of that inset side 80 away from the support member 66. The resilient force provided by the biased tab 40 contact with the inset side surface 88 also allows some horizontal movement of the inset side 80, for example to accommodate cover board shrinkage or swelling, however vertical movement the inset side 80 is substantially limited.

Cover boards 60 are typically disposed so that they are generally perpendicular to the support member 66. As shown in FIG. 11 the disclosed clip 10 may also be used to fasten cover boards 60 that are disposed with respect to the support member 66 at angles other than ninety degrees.

In many instances the cover boards will not span the entire length of the framework. Thus, as shown in FIG. 12, two cover boards 60e, 60f may need to be disposed in end to end relationship. Typically, the abutting ends 72, 74 of the cover boards 60e, 60f are positioned over a support member 66 for support. The clip 10 may also be used to fasten abutting cover boards 60e, 60f disposed in such end to end relationship to a support member 66. In this application, elongated fasteners 112 can be disposed through all of the apertures 30. In a less preferred variation a single fastener 112 can be disposed through only the aperture 30 overlying the support member 66.

While preferred embodiments of the foregoing invention have been set forth for purposes of illustration, the foregoing description should not be deemed a limitation of the invention herein. Accordingly, various modifications, adaptations and alternatives may occur to one skilled in the art without departing from the spirit and scope of the present invention.

What is claimed:

1. A clip for helping secure a profiled board to a support member, the profiled board comprising a generally planar exposed surface defined between first and second longitudinally extending edges, a generally planar support surface opposite the exposed surface, positionable adjacent the support member and defined between first and second longitudinally extending edges, a longitudinally extending, protruding side projecting outwardly from the first exposed and first support edges and a longitudinally extending inset side projecting inwardly from the second exposed and second support edges, wherein the clip comprises:
a body including opposing ends, a longitudinal edge disposed between the ends, an inner surface positionable in contact with the protruding side when the board is secured to the support member, an outer surface opposing the inner surface, an aperture defined in the body and connecting the inner surface and the outer surface; and
a tab projecting from the body, the tab including a distal end, an inner surface disposable at a first position with respect to the protruding side when the board is secured to the support member and an outer surface opposing the inner surface, the tab being elastically movable to a second position that is closer to the protruding side than the first position, wherein the tab does not substantially penetrate into the board as the board is secured to the support member.

2. The clip of claim 1 wherein the body and tab are rounded.

3. The clip of claim 1 comprising a tab stop projecting from the tab distal end, wherein the tab stop does not substantially penetrate into the board when the clip is used to help secure the board to the support member.

4. The clip of claim 1 wherein the body is longitudinally elongated in a direction between the ends, the body defines a plurality of longitudinally spaced apertures therethrough and a plurality of longitudinally spaced tabs project from the body, each tab having a first position wherein the tab inner surface is disposed at a first angle of no more than about 180 degrees to the body inner surface, each tab elastically movable independent of the other tabs to a second position wherein that tab inner surface is disposed at a second angle to that body inner surface that is less than that tab first angle.

5. The clip of claim 1, wherein the profiled board comprises an axis parallel to and defined between the exposed surface and the support surface, the protruding side comprises a first longitudinally extending, generally planar surface in acute angular relationship to the exposed surface and in acute angular relationship to the axis and a second longitudinally extending, generally planar surface in acute angular relationship to the support surface and in acute angular relationship to the axis, the first outwardly projecting surface intersecting the second outwardly projecting surface; and comprising a second profiled board having a generally planar exposed surface defined between first and second longitudinally extending exposed edges, an opposing generally planar support surface positionable adjacent the support member and defined between first and second longitudinally extending support edges, an axis parallel to and defined between the exposed surface and the support surface, and a longitudinally extending, inset side projecting inwardly from the second exposed and second support edges and positionable adjacent the first profiled board protruding side, the inset side comprising, a first longitudinally extending, generally planar surface in angular relationship to the exposed surface and in acute angular relationship to the axis, and a second longitudinally extending, generally planar surface in angular relationship to the support surface and in acute angular relationship to the axis, the first inwardly projecting surface intersecting the second inwardly projecting surface, wherein:
the tab projects from the longitudinal edge, the tab inner surface is disposed in angular relationship to the body inner surface, the clip body is positionable between the first board protruding side first surface and the adjacent second board inset side first surface and the tab is positionable between the first board protruding side second surface and the adjacent second board inset side second surface so that the tab resiliently biases the second board inset edge away from the first board protruding edge.

6. The clip of claim 1 wherein the body outer surface is substantially planar and comprising a depressed body portion that is adjacent to the aperture and below the planar surface.

7. The clip of claim 1 wherein the tab inner surface is disposed at an angle in the range of about 45 degrees to about 180 degrees with respect to the body inner surface.

8. The clip of claim 1 wherein the clip longitudinal edge extends substantially continuously from one end of the clip body to the opposing end.

9. An profiled board comprising:
a generally planar exposed surface defined between first and second longitudinally extending exposed edges, an opposing generally planar support surface defined between first and second longitudinally extending support edges and an axis parallel to and defined between the exposed surface and the support surface;
a longitudinally extending protruding side projecting outwardly from the first exposed and first support edges, comprising,
a first outwardly projecting, longitudinally extending, generally planar surface in acute angular relationship to the exposed surface and in acute angular relationship to the axis,
a second outwardly projecting, longitudinally extending, generally planar surface in acute angular relationship to the support surface and in acute angular relationship to the axis, the first outwardly projecting surface intersecting the second outwardly projecting surface; and
a longitudinally extending inset side projecting inwardly from the second exposed and second support edges, comprising,
a first inwardly projecting, longitudinally extending, generally planar surface in angular relationship to the exposed surface and in acute angular relationship to the axis,
a second inwardly projecting, longitudinally extending, generally planar surface in angular relationship with the support surface and at an acute angle to the axis, the first inwardly projecting surface intersecting the second inwardly projecting surface.

10. The board of claim 9 wherein the first outwardly projecting surface and the second outwardly projecting surface are each independently at an angle of about 30 degrees to about 60 degrees with respect to the axis and the first inwardly projecting surface and the second inwardly projecting surface are each independently at an angle of about 30 degrees to about 60 degrees with respect to the axis.

11. The board of claim 9 wherein the first outwardly projecting surface comprises a longitudinally extending projection adjacent to the exposed surface.

12. The board of claim 9 wherein the first outwardly projecting surface comprises a longitudinally extending projection adjacent to the exposed surface and the second outwardly projecting surface comprises a longitudinally extending projection adjacent to the support surface.

13. The board of claim 9, comprising:
a rib extending from the first outwardly projecting surface adjacent to the exposed surface and longitudinally extending along the length of the board, wherein;
the first outwardly projecting surface intersects the second outwardly projecting surface to form a longitudinally extending radiused surface at about the axis;
a radius is formed at the intersection of the first inwardly projecting surface and the exposed surface;
a radius is formed at the intersection of the second inwardly projecting surface and the support surface;
the first inwardly projecting surface intersects the second inwardly projecting surface at about the axis; and
each of the first and second outwardly projecting surfaces are at an angle of about 30 degrees to about 60 degrees with respect to the axis and each of the first and second inwardly projecting surfaces are at an angle of about 30 degrees to about 60 degrees with respect to the axis.

14. A system for hidden fastening of boards to a support member, comprising:
a support member;
a first elongated, profiled board comprising a generally planar exposed surface defined between first and second longitudinally extending exposed edges, a generally planar support surface opposite the exposed surface, adjacent the support member and defined between first and second longitudinally extending support edges, an axis parallel to and defined between the exposed surface and the support surface, a longitudinally extending, protruding side projecting outwardly from the first exposed and first support edges and a longitudinally extending inset side opposite the protruding side and projecting inwardly from the second exposed and second support edges;
a second elongated, profiled board comprising a generally planar exposed surface defined between first and second longitudinally extending exposed edges, a generally planar support surface opposite the exposed surface, adjacent the support member and defined between first and second longitudinally extending support edges, an axis parallel to and defined between the exposed surface and the support surface, a longitudinally extending, protruding side projecting outwardly from the first exposed and first support edges and a longitudinally extending inset side opposite the protruding side and projecting inwardly from the second exposed and second support edges, the second board inset side being in side by side relationship to the first board protruding side;
a clip disposed between the first board protruding side and the second board inset side, the clip comprising a body including opposing ends, a longitudinal edge disposed between the ends, an inner surface in contact with the first board protruding side, an outer surface facing the second board inset side, an aperture connecting the inner surface and the outer surface, and a tab projecting from the body, the tab including a free end, a tab inner surface adjacent the first board protruding side and an opposing tab outer surface facing the second board inset side, wherein the tab does not substantially penetrate into the first board or the second board; and
an elongated fastener disposed through the clip aperture, through the first board protruding side and partially into the support member.

15. The system of claim 14 wherein:
the first board protruding side comprises a first outwardly projecting, longitudinally extending, generally planar surface in acute angular relationship to the exposed surface and in acute angular relationship to the axis and a second outwardly projecting, longitudinally extending, generally planar surface in acute angular relationship to the support surface and in acute angular relationship to the axis, the first outwardly projecting surface intersecting the second outwardly projecting surface;
the first board inset side comprises a first inwardly projecting, longitudinally extending, generally planar surface in angular relationship to the exposed surface and in acute angular relationship to the axis and a second inwardly projecting, longitudinally extending, generally planar surface in angular relationship to the support surface and at an acute angle to the axis, the first inwardly projecting surface intersecting the second inwardly projecting surface;
the second board protruding side comprises a first outwardly projecting, longitudinally extending, generally planar surface in acute angular relationship to the exposed surface and in acute angular relationship to the axis and a second outwardly projecting, longitudinally extending, generally planar surface in acute angular relationship to the support surface and in acute angular relationship to the axis, the first outwardly projecting surface intersecting the second outwardly projecting surface;
the second board inset side comprises a first inwardly projecting, longitudinally extending, generally planar surface in angular relationship to the exposed surface and in acute angular relationship to the axis and a second inwardly projecting, longitudinally extending, generally planar surface in angular relationship to the support surface and in acute angular relationship to the axis, the first inwardly projecting surface intersecting the second inwardly projecting surface; and
the tab inner surface is disposed at an angle of no more than about 180 degrees to the body inner surface

16. The system of claim 14 comprising a tab stop projecting from the tab free end, the tab stop including an inner surface and an opposing outer surface, wherein the tab stop does not substantially penetrate into the first board.

17. The system of claim 14 wherein:
the first board protruding side comprises a first outwardly projecting, longitudinally extending, generally planar surface in acute angular relationship to the exposed surface and in acute angular relationship to the axis and a second outwardly projecting, longitudinally extending, generally planar surface in acute angular relationship to the support surface and in acute angular relationship to the axis, the first outwardly projecting surface intersecting the second outwardly projecting surface;
the first board inset side comprises a first inwardly projecting, longitudinally extending, generally planar surface in angular relationship to the exposed surface and in acute angular relationship to the axis and a second inwardly projecting, longitudinally extending, generally planar surface in angular relationship to the support surface and at an acute angle to the axis, the first inwardly projecting surface intersecting the second inwardly projecting surface;
the second board protruding side comprises a first outwardly projecting, longitudinally extending, generally planar surface in acute angular relationship to the exposed surface and in acute angular relationship to the axis and a second outwardly projecting, longitudinally extending, generally planar surface in acute angular relationship to the support surface and in acute angular relationship to the axis, the first outwardly projecting surface intersecting the second outwardly projecting surface;
the second board inset side comprises a first inwardly projecting, longitudinally extending, generally planar surface in angular relationship to the exposed surface and in acute angular relationship to the axis and a second inwardly projecting, longitudinally extending, generally planar surface in angular relationship to the support surface and in acute angular relationship to the axis, the first inwardly projecting surface intersecting the second inwardly projecting surface; and
the clip body inner surface is in contact with the first board, first outwardly projecting surface, the clip outer surface is spaced from the second board, first inwardly projecting surface, the tab inner surface is spaced from the first board, second outwardly projecting surface and the tab outer surface resiliently biases the second board, second inwardly projecting surface.

18. The system of claim 14 wherein:
the first board protruding side comprises a first outwardly projecting, longitudinally extending, generally planar surface in acute angular relationship to the exposed surface and in acute angular relationship to the axis and a second outwardly projecting, longitudinally extending, generally planar surface in acute angular relationship to the support surface and in acute angular relationship to the axis, the first outwardly projecting surface intersecting the second outwardly projecting surface;
the first board inset side comprises a first inwardly projecting, longitudinally extending, generally planar surface in angular relationship to the exposed surface and in acute angular relationship to the axis and a second inwardly projecting, longitudinally extending, generally planar surface in angular relationship to the support surface and at an acute angle to the axis, the first inwardly projecting surface intersecting the second inwardly projecting surface;
the second board protruding side comprises a first outwardly projecting, longitudinally extending, generally planar surface in acute angular relationship to the exposed surface and in acute angular relationship to the axis and a second outwardly projecting, longitudinally extending, generally planar surface in acute angular relationship to the support surface and in acute angular relationship to the axis, the first outwardly projecting surface intersecting the second outwardly projecting surface;
the second board inset side comprises a first inwardly projecting, longitudinally extending, generally planar surface in angular relationship to the exposed surface and in acute angular relationship to the axis and a second inwardly projecting, longitudinally extending, generally planar surface in angular relationship to the support surface and in acute angular relationship to the axis, the first inwardly projecting surface intersecting the second inwardly projecting surface; and
the intersection of the first board first and second outwardly projecting surfaces is disposed within the second board inset side.

19. The system of claim 14 wherein the tab resiliently biases the second board.

20. The system of claim 14 wherein the second board inwardly projecting surface is free from penetration by the clip or the fastener.

21. The system of claim 14 wherein the clip does not substantially penetrate into the first board or the second board.

22. A method for hidden fastening of boards to a support member, comprising:
providing a support member;
providing a first elongated, profiled board comprising a generally planar exposed surface defined between first and second longitudinally extending exposed edges, a generally planar support surface opposite the exposed surface, adjacent the support member and defined between first and second longitudinally extending support edges, an axis parallel to and defined between the exposed surface and the support surface, a longitudinally extending, protruding side projecting outwardly from the first exposed and first support edges and a longitudinally extending inset side opposite the protruding side and projecting inwardly from the second exposed and second support edges;
disposing the first board support surface adjacent the support member;
disposing a clip inner surface in contact with the first board protruding side, the clip comprising a body including opposing ends, a longitudinal edge disposed between the ends, an outer surface opposing the inner surface, an aperture connecting the inner surface and the outer surface, and a tab projecting from the body, the tab including a free end, an inner surface and an opposing outer surface, wherein the tab does not substantially penetrate into the first board;
disposing a shank of an elongated fastener through the clip aperture and through the first board and partially into the support member;
providing a second elongated, profiled board comprising a generally planar exposed surface defined between first and second longitudinally extending exposed edges, a generally planar support surface opposite the exposed surface, adjacent the support member and defined between first and second longitudinally extending support edges, an axis parallel to and defined between the exposed surface and the support surface, a longitudinally extending, protruding side projecting outwardly from the first exposed and first support edges and a longitudinally extending inset side opposite the protruding side and projecting inwardly from the second exposed and second support edges; and
disposing the second board support surface adjacent the support member and the second board inset side in side by side relationship to the first board protruding side, wherein a portion of the first board protruding side is disposed within the second board inset side, a portion of the clip is disposed within the second board inset side and the clip resiliently biases the second board inset side.

23. The method of claim 22, wherein the protruding side comprises a first outwardly projecting, longitudinally extending, generally planar surface in acute angular relationship to the exposed surface and in acute angular relationship to the axis and a second outwardly projecting, longitudinally extending, generally planar surface in acute angular relationship to the support surface and in acute angular relationship to the axis, the first outwardly projecting surface intersecting the second outwardly projecting surface.

24. The method of claim 22, wherein the clip does not substantially penetrate into the first board, the second board or the support member.
